(19) United States
(12) Patent Application Publication
(10) Pub. No.: US 2002/0119399 A1
(43) Pub. Date: Aug. 29, 2002

(54) Laser fabrication of rotary printing screens

(76) Inventor: Jesse E. Leskanic, Gaffney, SC (US)

Correspondence Address: ALSTON & BIRD LLP, BANK OF AMERICA PLAZA, 101 SOUTH TRYON STREET, SUITE 4000, CHARLOTTE, NC, 28280-4000, US

(21) Appl. No.: 09/793,438

(22) Filed: Feb. 26, 2001

(51) Int. Cl. G03F 7/00

(52) U.S. Cl. 430/320; 430/323; 430/327; 430/396

(57) ABSTRACT

The invention relates to methods of manufacturing a printing screen that is operable for use in a rotary screen printing process, wherein a metallic sheet having a generally cylindrical shape is positioned adjacent a laser. The metallic sheet is rotated about its longitudinal axis, and the laser is moved along a path parallel to the longitudinal axis. The laser directs focused radiation to the metallic sheet such that holes are formed therethrough. Portions of the metallic sheet are vaporized, which leaves the metallic sheet substantially free of slag. In this regard, the metallic sheet can be formed from a single layer having at least one exposed surface, such that the focused radiation contacts only the metallic sheet.

### FIELD OF THE INVENTION

The present invention relates to the formation of metal printing screens, and more particularly relates to the use of a laser for direct production of patterned rotary screens from metal foils, which are suitable for screen printing of textile fabrics, paper, vinyl wallpaper, and other materials.

### BACKGROUND OF THE INVENTION

Traditional approaches to the production of rotary “halftone” printing screens is a complicated multi-step operation that utilizes traditional photographic processes. For example, a conventional method for forming a rotary screen includes painting or drawing a design on paper, canvas, or similar substrate, scanning the design to produce a digital copy, and editing the digital copy to fix any errors generated by producing the digital copy. The digital copy is then reproduced on a photographic film.

A metallic cylindrical mesh screen, which can be purchased from a traditional screen manufacturer, is coated with a photosensitive polymer emulsion. The mesh is comprised of a plurality of cells, which typically range from about 1600-40,000 cells per square inch, and particularly about 14,400 cells per inch. The cells maintain the physical integrity of the screen while providing fine definition to the finished design. The coated screen is then dried, and the photographic film having the desired design is wrapped around the screen. The screen is then exposed to some form of radiation, which impacts the non-opaque areas of the photographic film and the underlying photosensitive emulsion. The radiation causes the impacted photosensitive emulsion to become cross-linked and thus resist subsequent rinsing processes. By contrast, the areas of the emulsion-coated screen that are covered by the opaque portions of the film and thus have not been exposed to the radiation are easily washed out of the screen using water. This is known as the developing process, which creates a negative image of the desired design on the screen. The “open” areas of the screen are simply the exposed mesh of the underlying screen. During the printing process, colored print paste pass through the mesh and onto a printing substrate.

After the developing process the screen is placed in an oven and baked until the polymer emulsion is fully cured. After developing and baking, end rings or caps are installed into the cylindrical screen and the screen is then ready for use in rotary screen printing. The total cycle time to complete the screen is often between 8-10 days. The resulting screen, which is known as a “lacquer” screen, is typically used for solid color applications and fine line detail.

Other techniques are also used to produce rotary screens for decorative printing. For example, U.S. Pat. No. 5,327,167 describes laser engraving of a conventional mesh screen that has been coated with a photographic polymer emulsion and cured. A patterned screen having a finished, predetermined design is produced by using the laser, which is typically a continuous wave laser having a power rating of 500-1200 watts, to burn off the cured polymeric coating or emulsion in areas of the screen that are desired to be left open. In these open areas of the pattern, the mesh features of the original screen are thus exposed as discussed above. The finished screen is similar to that described above using photosensitive polymer emulsion techniques.

These methods, however, suffer from several disadvantages. In particular, the use of photographic emulsion is costly and tedious, as the thickness of the emulsion applied to the screen must be consistent. In addition, the developing process delays the formation of the finished screen and uses many raw materials. The laser engraving technique avoids the need to go through development and washing steps of the screen by enabling the screen to be patterned directly by a laser without the need for the intermediate photographic film. However, laser engraving techniques still require the costly and tedious steps of applying and curing a photosensitive emulsion to a pre-formed mesh screen.

Another problem with laser engraving techniques is the generation of irregular patterns due to inconsistent hole alignment in the emulsion layer and the underlying mesh screen. It is generally noticed, specifically at the places at which the desired design requires that the hardened emulsion layer span only a portion of a cell in the mesh screen, that the emulsion layer is not strong enough to partially span the cell and thus is entirely removed from the cell. The consequence of this complete removal is that during the printing operation, a considerable degree of definition loss is noticed at the edges of patterns. This serration effect that is created is very disadvantageous, especially when forming patterns of very fine detail. Another disadvantage is that often a cell formed in the hardened emulsion is partially filled by the underlying mesh, thus reducing definition of the printed pattern.

Yet another problem with lacquer screens is that such screens perform poorly when creating tonal designs. In particular, the cells of the underlying mesh can create a speckled or dotted appearance if colors are overlapped. This occurs because the hole size of the screen is determined by the underlying cells of the mesh screen, which comprises a high-density uniform grid of cells. Since quality tonal designs are created by varying the size and density of the holes, the rigid and uniform cell spacing of lacquer screens results in poor-quality tonal designs.

Another method for production of rotary printing screens utilizes a process known as the Galvano process. Instead of coating a mesh screen, the Galvano process involves coating a smooth, clean mandrel with a photosensitive polymer emulsion, which is then allowed to air dry. A photographic film having a desired design superimposed thereupon is placed over the mandrel, and the coated mandrel is exposed to ultraviolet radiation. After exposure to ultraviolet radiation, the mandrel is washed with a solvent to remove all unexposed portions of the photosensitive emulsion, while leaving areas of exposed polymer in the negative image that is desired to be produced. The final step in production of a Galvano screen is electroplating nickel on the mandrel. During the electroplating process the hardened emulsion resists the nickel such that the nickel occupies the spaces left by the unexposed emulsion that was washed away. In this manner, a plurality of small holes (similar to the open mesh cells of traditional screens) are defined for permitting the print paste to pass through the screen during the printing process. The resulting nickel screen is then peeled away from the mandrel and is ready for use in a subsequent printing process.

Galvano screens perform well for tonal designs because the holes of the screen can be varied in both size and density to create the desired color intensity. The holes can be varied because Galvano screens do not incorporate an underlying mesh screen as in lacquer screens. The result is clear tonal designs of much higher quality than with lacquer screens. However, Galvano screens are made with only about 3600 cells per square inch, which therefore limits their ability to create fine lines and high definition designs.

Variations and improvements of the Galvano process have also been developed. For example, U.S. Pat. No. 5,338,627 describes using a laser in conjunction with the Galvano process for producing a seamless rotary screen. In this process, the mandrel having a cured photosensitive emulsion coating is rotated at a predetermined speed. The spinning mandrel is exposed to a laser beam to digitally create a pattern in the photosensitive material. The coated mandrel then undergoes a developing and washing process as discussed above, which leaves areas of the hardened photosensitive emulsion on the mandrel to serve as a resist in the Galvano electroplating operation. The mandrel is then electroplated, and the resulting nickel sleeve is removed and used as a rotary screen.

While Galvano methods of making rotary screens eliminate the mesh screens used in more traditional screen production, Galvano methods still require the use of photographic emulsions and other photographic techniques. This adds time and expense to the screen production. Another problem with Galvano methods is that the small holes formed in the resulting nickel screen have a frustoconical shape, wherein the smaller diameter of the hole is on the outer surface of the screen and the larger diameter of the hole is on the inner surface of the screen. This occurs because as the nickel layer thickens during the electroplating process, the nickel begins to cover over the areas of hardened emulsion left on the mandrel from the development process. As the nickel covers over the emulsion, which is typically a plurality of small dots or cylinders arranged according to the desired design, the nickel forms a decreasing radius shell about the emulsion, resulting in the frustoconical shape of the nickel sleeve.

The frustoconical shape of the holes formed by the Galvano process may cause many problems. One particular problem is that the shape creates a venturi effect when print paste is directed through the holes. In particular, the frustoconical holes increase the hydraulic pressure of the print paste (compared to cylindrical holes) as the paste passes from inside the screen to the outer surface of the screen and into an adjacent printing substrate. By decreasing the diameter of the hole along the print paste's path of travel, the print paste accelerates and is forced deeper into the printing substrate. This, in turn, results in less definition of the design.

From the foregoing it can be seen that designs requiring both high definition and tonal features create a dilemma when choosing the particular printing screen for the application. Attempts have been made to achieve the benefits of both lacquer screens and Galvano screens in the same design by using both types of screens in the same printing machine on the printing substrate. But this creates even more difficulty and sources of error, as the diameters and circumferences of the two screens are difficult to match. Moreover, this also adds to the complexity and cost of the printing process.

U.S. Pat. No. 5,304,772 discloses yet another process for producing a metal screen by irradiating a composite material having a central metal layer. The central metal layer is coated or surrounded on both sides by release layers, and an outer metal layer surrounds the central metal layer and release layers. Focused radiation is then directed to the composite, which melts a hole through the outer layer, release layers, and central metal layer. According to the '772 patent, the melted metal forms slag or crust around the edges of the hole produced by the radiation. Slag buildup is a particular problem when forming screens out of copper, since copper is relatively soft and melts when struck by focused radiation. In order to prevent formation of slag on the central layer, the central layer is surrounded by the release layers and outer metal layer. This places the central layer, which is to become the screen, in the middle of a five layer composite (including the underlying mandrel). The slag then collects on the outer layer rather than on the central layer.

Thus, the '772 patent is directed to a method of removing slag buildup by providing a multi-level composite wherein the layer intended for use as the printing screen is surrounded by several other layers that are discarded after formation of holes through the composite. The advantage of forming a composite as described by the '772 patent eliminates the need to remove the slag or other imperfections in a subsequent mechanical step, such as using a diamond cutter. Yet the 772 patent leaves much to be desired, since coating or adding multiple layers to form a composite adds time and expense to the manufacturing process.

Each of the above methods for producing rotary screens involves several complicated processing steps, such as coating screens or mandrels with photographic polymer emulsions or stacking several layers together to form a composite. The above methods may also involve removal of exposed polymer with a laser, coating metal cylinders with release materials, or electroplating metal using the Galvano process. These processes are lengthy to perform, are expensive to carry out, and use several raw materials in forming the finished screen.

Another problem common to these methods of producing rotary printing screens is that the screens typically are shipped from the screen manufacturers to the screen printing locations, which can be thousands of miles away from the screen producers. Due to the time-intensive and inexact methods practice heretofore, screen printers typically order duplicate screens in order to minimize printing downtime if a screen becomes damaged. This only adds to the overall cost of the screen printing and wastes material, particularly if the duplicate screens are never needed.

Thus, there is a need for improvement of the current state of the art. In particular, it is desirable to provide a method of producing a rotary printing screen that does not suffer from the high cost and long production time issues associated with conventional methods. In particular, it is desirable to form a rotary printing screen without the use of photographic emulsions or by combining several layers into a composite during the formation of the screen. It is further desirable to form a single screen that exhibits the advantages of both lacquer screens and Galvano screens, namely high resolution and the ability to create high quality tonal designs, respectively. It is further desirable to provide a method of producing a rotary printing screen that minimizes shipping times and distances of the printing screens to avoid damaging the screens.

### SUMMARY OF THE INVENTION

The present invention overcomes the disadvantages of conventional methods by providing a method for producing a rotary screen from a thin-walled metallic sheet using highly focused energy, such as is attained with a laser, to create a plurality of holes directly through the metallic sheet in a predetermined pattern according to a desired design. Advantageously, the present invention does not involve the coating of preformed mesh screens with photosensitive emulsions, exposure of photosensitive emulsions to radiation, removal of hardened polymer masks with lasers, removal of unhardened emulsion with chemical washes, or electroplating to form a rotary screen. By contrast, the metallic sheet is the only raw material used in the manufacture of the screen according to one embodiment of the present invention. Moreover, the present invention uses highly focused energy such that slag or other physical impediments are avoided during the formation of the rotary screen. In this manner, multiple layer composite formations are not necessary when forming the holes or perforations in the metallic sheet. Thus, the present invention provides improvements in production time, economics, and raw material use.

Advantageously, the rotary screen of the present invention exhibits the desirable characteristics of both lacquer screens and Galvano screens. In particular, the rotary screen of the present invention is capable of producing fine details as well as or better than lacquer screens, while also providing high quality tonal patterns.

In particular, the present invention provides a method of manufacturing a printing screen that is operable for use in a rotary screen printing process, which according to one embodiment includes the steps of positioning a metallic sheet, such as a thin-walled nickel cylinder having a thickness of about 0.0005-0.010 inches, proximate a laser. The laser is preferably housed in a laser engraving machine that is known in the art. Advantageously, the metallic sheet is rigid enough to maintain a cylindrical shape without the use of a mandrel. Thus, the metallic sheet can be housed in the laser engraving machine by inserting supports or end caps in the opposing ends of the cylindrical metallic sheet that support the metallic sheet during subsequent processing. During the hole formation process, however, an internal support ring can be used adjacent the point of radiation impingement to prevent deflection of the metallic sheet.

The metallic sheet and laser are moved relative to one another, preferably by rotating the metallic sheet about its longitudinal axis while moving the laser along a path parallel with the longitudinal axis of the metallic sheet. As the metallic sheet is rotating and the laser is moving along the path parallel to the longitudinal axis of the metallic sheet, the laser directs focused radiation, such as a laser beam, onto the metallic sheet to form a plurality of holes therethrough.

According to one embodiment, the focused radiation contacts only the metallic sheet. In this regard, the only raw material is the metallic sheet, whereby no extra layers are coated or attached to the metallic sheet. The laser is tuned to directly impact the metallic sheet and form the plurality of holes therethrough. Other methods may also be used to form the plurality of holes in the metallic sheet. For example, in another embodiment the laser is directed to the metallic sheet and one other layer, which is disposed on one side of the metallic sheet. This other layer may be used for one or more various reasons, but it is not required for the production of the finished screen according to the present invention.

The laser used in conjunction with the present invention is preferably one that is commonly available and known in the art. However, the laser is tuned or adjusted in a new way to direct focused radiation to the metallic sheet. The laser is preferably a pulsable laser, which directs energy pulses at a rate of up to 500,000 Hz to the metallic sheet. Because of the large number of energy pulses directed to the metallic sheet, the laser used in the present invention has a relatively low power rating of 25-100 watts compared to conventional lasers used to burn off the photosensitive emulsion.

The laser can also be tuned to provide cylindrical or frustoconical holes in the metallic sheet. More specifically, the frustoconical holes created according to the present invention are opposite those formed by the Galvano method discussed above. Contrary to the Galvano holes, the frustoconical holes created by the present invention have a greater diameter at the outer surface of the metallic sheet and a smaller diameter at the inner surface of the metallic sheet. Accordingly, print paste passing through the frustoconical holes of the present invention does not accelerate into the printing substrate, which may cause a loss of definition to the printed design.

Due at least in part to the laser and the metallic sheet according to the present invention, slag or other physical deposits are substantially eliminated during the formation of the printing screen. In particular, the material forming the metallic sheet, which preferably is completely formed of nickel or substantially formed of nickel, vaporizes when struck by the focused radiation directed from the laser. The vaporized material is drawn away by a vacuum, and slag is virtually non-existent on the surface of the metallic sheet.

Accordingly, the present invention provides methods for manufacturing a printing screen that is operable for use in a rotary screen printing process that overcome the disadvantages of conventional methods. In particular, the methods according to the present invention eliminate the use of photographic emulsions and techniques, which greatly speeds the production time of the screen while saving cost and raw material use. The method of the present invention require only the metal sheet as a raw material, so that wasteful, multiple layer composites are not necessary to form the holes in the metallic sheet. Thus, the methods of the present invention greatly improve the current state of the art in terms of cost, raw material use, and production time.

Furthermore, the methods of the present invention allow for the screens to be formed at the same location where the screen printing occurs. While this beneficial arrangement has been reserved primarily only for large screen printing facilities that can afford to support the cumbersome screen manufacturing machinery and the screen printing machinery, the methods of the present invention allow for small screen printing operations to form their own screens quickly and easily. In one embodiment, a screen printing operation supplies a desired design, which can be in digital form or non-digital form, to a remote location, such as a third party location, to convert the desired design to final digital form. The remote location then returns the final digital form, where it is loaded into the laser engraving machine to form the finished printing screen. If the finished screen is somehow damaged or unusable, the screen printing operation can quickly make a replacement screen using a standard metallic sleeve. Thus, the methods of the present invention eliminate the need for a screen printing operation to purchase multiple screens in order prevent long downtimes, since printing screens can be quickly and easily formed according to the present invention.

### BRIEF DESCRIPTION OF THE DRAWINGS

Having thus described the invention in general terms, reference will now be made to the accompanying drawings, which are not necessarily drawn to scale, and wherein:

FIG. 1 is a perspective view of a laser engraving machine and a generally cylindrical sheet positioned therein for forming a finished screen according to one embodiment of the present invention;

FIG. 2 is a perspective view of a blank metallic sheet having supports positioned at opposing ends so that the metallic sheet can be positioned in the laser engraving machine shown in FIG. 1;

FIG. 3 is a cross-sectional view of the blank metallic sheet and support as shown along lines 3-3 of FIG. 2;

FIG. 4 is a perspective view of a metallic sheet being rotated while a laser creates a plurality of openings therethrough according to one embodiment of the present invention;

FIG. 5 is a greatly enlarged surface view of a plurality of openings formed in the metallic sheet according to one embodiment of the present invention;

FIGS. 6-6A are cross-sectional views of the plurality of openings formed in the metallic sheet shown along lines 6-6 of FIG. 5;

FIG. 7 is a greatly enlarged perspective view of a cylindrical opening formed in the metallic sheet according to one embodiment of the present invention;

FIG. 8 is a greatly enlarged cross-sectional view of a frustoconical opening formed in the metallic sheet according to another embodiment of the present invention;

FIG. 9 is a greatly enlarged perspective view of a frustoconical opening formed in the metallic sheet according to the other embodiment of the present invention; and

FIG. 10 is a schematic diagram showing a transfer between a printing location and a remote location according to one embodiment of the present invention.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

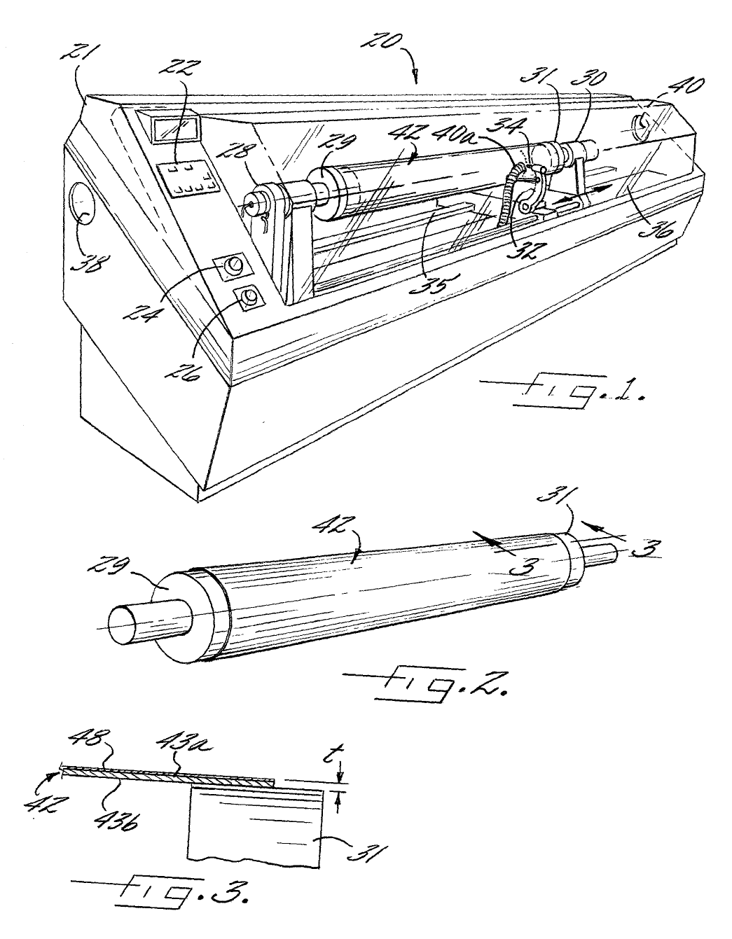

As shown in FIG. 1, the process according to one embodiment of the present invention involves forming a metallic rotary printing screen by utilizing a laser engraving machine 20. Laser engraving machines are known in the art of screen printing, such as ScreenMaster™ laser engraving machines manufactured by ZED Instruments, Ltd. of Surrey, England. A typical engraving machine 20 includes a sealable cabinet 21 with a cover 36 operable to move between opened and closed positions. Inside the cabinet 21, the engraving machine 20 includes a rotatable headstock 28 and tailstock 30 having respective screen carriers 29 and 31. A control panel 22 is positioned on the cabinet 21, and includes controls for prescribing the rotational speed of the headstock 28 via a servomotor (not shown) that is mounted in the headstock. Others controls are also provided on the control panel 22, as discussed more fully below.

The engraving machine 20 also includes an engraving head 32 movably positioned inside the cabinet 21. The engraving head 32 is operably connected to the control panel 22, and includes a laser 34 capable of emitting focused radiation, such as a laser beam. An output lens (not shown) is mounted within the engraving head 32 for focusing the laser beam. As is conventionally known, the laser 34 and output lens are mounted in an aluminum block through which cooling water is passed. Additionally, the lens must be kept clean and any debris in the path of the laser beam must be kept to a minimum. This is achieved by using a supply of compressed air (not shown) that exhausts proximate to where the laser beam emerges.

The laser engraving machine 20 also includes a track 35 on which the engraving head 32 is movably mounted so that the engraving head and laser 34 move in a linear path between the headstock 28 and tailstock 30. The control panel 22 also includes controls for adjusting and controlling the laser 34 and cover 36. Other operational features are also provided, such as indicator lights 24 and an emergency stop 26.

The laser engraving machine 20 also includes a vacuum having a vacuum inlet 38 and a vacuum outlet 40 for removing particles from inside the cabinet 21 of the laser engraving machine 20. In particular, the vacuum is to assure that respirable particles of nickel, e.g., particles in the range of 0.5-7 microns, produced in the screen formation process are removed from the cabinet 21 and collected on filters so that the air can be safely returned to the work environment. In one embodiment, fresh air enters the cabinet 21 at the vacuum inlet 38 and exits via a vacuum snout 40A and/or a high-speed blower/vacuum outlet 40 at the opposite end of the cabinet from the vacuum inlet. Alternatively, air may enter from both ends of the cabinet 21 and exit from the middle of the cabinet.

The high-speed blower/vacuum outlet 40 preferably creates an air sweep of about 100-300 cfm through the cabinet 21 to transport particles out of the cabinet and into a filtration system (not shown). In one embodiment, the air and particles exiting the cabinet 21 pass through a sedimentation chamber where heavier particles are allowed to fall out. The remaining particles pass through a bank of cartridge filters to remove respirable-sized particles. The air and particles can also be directed through a HEPA filter if desired to assure complete removal of respirable particles. The air can then be exhausted to the work environment.

Turning to FIGS. 2 and 3, a metallic sheet 42 to be formed into the printing screen is placed in the laser engraving machine 20 and mounted to the headstock 28 and tailstock 30. More specifically, the metallic sheet 42 is releaseably attached or mounted to the associated screen supports 29 and 31 of the headstock 28 and tailstock 30, respectively, so that the metallic sheet and screen supports share a common longitudinal axis. The screen supports 29 and 31 are also compatible for use with metallic sheets with pre-mounted end caps (not shown for clarity). The screen carriers 29 and 31 preferably extend only a small distance inside the metallic sheet 42. This is because the metallic sheet 42 is strong enough to maintain its cylindrical shape without any added support. In particular, the thickness of the metallic sheet 42, the material comprising the metallic sheet, and any coatings applied thereto provide the necessary strength to the metallic sheet to maintain its cylindrical form. As a result, the metallic sheet 42 does not require the support of a mandrel extending substantially the length of the metallic sheet, which thereby reduces cost and complexity during the formation of the screen. An internal support (not shown) can also be used to prevent deflection of the metallic sheet 42 in subsequent processing. The metallic sheet 42 has a thickness t of about 0.0005-0.010 inches, and preferably about 0.002-0.005 inches, and is formed into a substantially cylindrical or tubular shape having an outer surface 43a and an inner surface 43b. This thickness has been shown to be preferable in the use of rotary screens because at this thickness the screen has enough physical strength and integrity to resist wear and damage during the screen printing process. Nevertheless, screens having greater or lesser thicknesses can also benefit from the practice of the teachings of the present invention.

In some instances, particularly where screens having less than 0.003 inches thickness are used, a coating 48 can be applied to the metallic sheet 42 to increase the toughness, strength, and resistance to physical deformation of the finished screen. The coating 48 provides resistance to damage by use and wear resistance comparable to at least that of screens having 0.003 inch thicknesses. The coating 48 may be applied to either side (or both sides) of the metallic sheet 42, and may be formed from polymeric, sintered, or electroplated materials. The coating 48 may also be selected to provide resistance to screen degradation from contact with corrosive chemicals. The coating 48 can also be selected to provide changes in surface energy of the screen, and thus improve the ease of cleaning the screens after use. These coatings 48 are known in the art. An example is Alcopoint Screen Shield, produced by Ciba Specialty Chemicals of Albemarle, N.C.

The metallic sheet 42 is formed from a resilient metal, such as nickel and alloys thereof. Metal is universally accepted as the standard material for rotary screen printing, as other materials, such as plastic, cannot withstand the rigors of the printing process and have been rejected by the industry. Nickel is preferable to other metals for its strength, chemical resistance, and resistance to wear. In addition, nickel tends to vaporize when struck by focused radiation instead of melting like copper or other metals. Thus, in order to avoid slag buildup from molten metal created by focused radiation, the metallic sheet 42 is preferably pure nickel. Other compositions can also be used, but they should be comprised substantially of nickel. For example, phosphorus can be added to the nickel in relatively small amounts, such as about 1-25%, without affecting the vaporizing qualities of the metallic sheet 42.

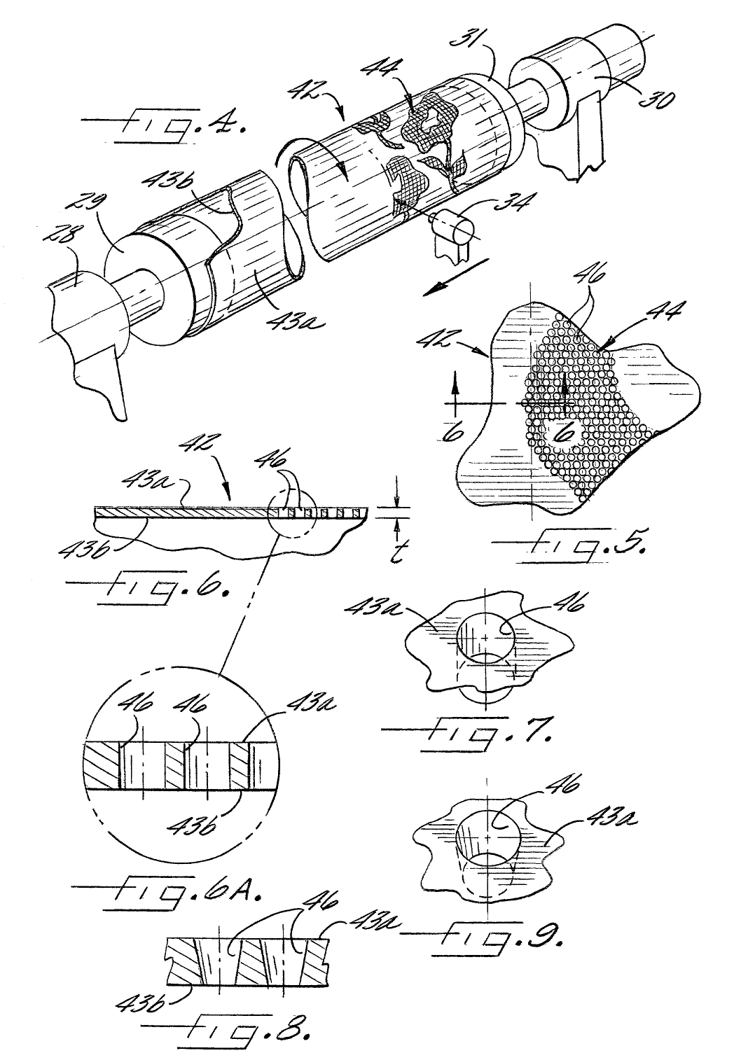

FIG. 4 shows the next step according to one embodiment of the present invention, wherein the mounted metallic sheet 42 is rotated about its longitudinal axis and a predetermined pattern or design 44, which has been loaded or programmed according to known techniques into the laser engraving machine 20, is created therethrough. As the metallic sheet 42 is rotated, which can be about 50 to 2000 RPM, and preferably about 1200 RPM, the engraving head 32 moves along the track 35 while “firing” or pulsing the laser 34. The laser 34 directs focused radiation, such as a laser beam, towards the metallic sheet 42 to reproduce the predetermined pattern 44 in the metallic sheet 42. Each time the laser 34 is pulsed, some of the metal comprising the metallic sheet 42 is vaporized and sucked away through the vacuum snout 40A and/or the high speed blower/vacuum outlet 40. When the predetermined pattern 44 according to the desired design is completed, the resulting rotary screen is immediately ready for use in the rotary screen printing of fabrics, paper, vinyl, and other materials.

The laser 34 preferably is an infrared laser, although ultraviolet lasers may also be used. The laser 34 fires or directs a plurality of radiation pulses, rather than a continuous wave of radiation, in order to produce a hole 46 of prescribed dimensions. Advantageously, the hole 46 can be of any dimension and can be grouped with other holes in clusters of any size desired. Compared to continuous wave lasers, which typically have power outputs of about 500-1200 watts, the laser 34 of the present invention preferably has a power output of about 25-100 watts, thus saving energy compared to conventional lasers.

The energy savings realized by utilizing a pulse laser instead of a continuouswave laser are substantial. In addition to the lower wattage of the pulse laser, the laser 34 is active for less time than a continuous wave laser, which therefore provides even more energy savings. Moreover, chillers (not shown), which are required for continuous wave lasers to prevent the laser from overheating, can be used less frequently or eliminated completely using a pulse laser. Finally, pulse lasers are also more reliable than continuous wave lasers and require much less maintenance.

Advantageously, however, the pulsable feature of the laser 34 permits the laser to deliver more focused radiation to the metallic sheet 42 than conventional lasers, despite the lower power output of the laser. This is accomplished by tuning and controlling the laser 34 to deliver a plurality of radiation pulses toward specified locations on the metallic sheet 42. An advantage of using a pulse laser is that the pulsed energy is compressed into short pulses of very great energy with many repetitions. For example, in a preferred embodiment the laser 34 is capable of firing up to about 500,000 times per second, or 500 KHz, which greatly compresses the time sequence of energy delivery to the metallic sheet 42. Accordingly, the relatively large number of pulses allows the power output of each pulse and thus the power output of the laser 34 to remain relatively low, which improves energy cost expenditures and efficiency of the process.

The pulses of radiation directly impinge the metallic sheet 42 to form holes 46 therethrough according to the predetermined pattern 44. More specifically, the laser 34 fires the radiation pulses at a rate synchronized with the rotational speed of the metallic sheet 42, and a sufficient number of pulses, such as between about 5-20 pulses, are fired from the laser at a specific location on the metallic sheet 42 to form the prescribed perforation or hole 46 in the metallic sheet 42. For example, ten (10) radiation pulses may be required to impact the metallic sheet 42 before a hole 46 is created therethrough. In this case, the engraving head 32 remains stationary on the track 35 while the metallic sheet rotates about its longitudinal axis. The laser 34 fires ten (10) radiation pulses toward the metallic sheet 42 that are synchronized with the sheet's rotational speed such that all ten of the radiation pulses impact at the same position on the metallic sheet.

This process is repeated at designated areas on the metallic sheet so as to produce the predetermined pattern 44. In a preferred embodiment, the desired holes 46 are formed about a particular circumferential path perpendicular to the longitudinal axis of the metallic sheet 42 before the engraving head 32 moves on a path parallel to the longitudinal axis of the metallic sheet along the track 35 to an adjacent circumferential path. In this regard, the predetermined pattern 44 is formed “one line at a time” as the engraving head 32 moves along the length of the metallic sheet 42 firing the laser 34. This is reflected in FIG. 4, which shows a section of the metallic sheet 42 wherein the predetermined pattern 44 has been formed by the laser 34, while a remaining section has yet to have the pattern formed therethrough.

The predetermined pattern 44 can be of any design that is amenable to the screen printing process. In this regard, the holes 46 formed in the metallic sheet 42 are spaced at different distances from each other as needed to produce the correct tonal qualities in the screen printing operation. In addition, the holes 46 have different diameters so that the finished screen will deliver the correct quantity of print paste to the substrate during printing and thus achieve the proper depth of shade on the printed substrate. The techniques of varying hole diameters and distances of holes from each other to produce a desired effect is well known to those skilled in the art of screen production.

Advantageously, the holes 46 forming the predetermined pattern 44 are formed directly in the metallic sheet 42. Thus, no photosensitive emulsions are used when forming a printing screen according to the present invention. Further, the methods of the present invention do not require a photographic film having a negative image of the predetermined pattern to be laid over the metallic sheet and exposed to radiation in order to create the predetermined pattern of the printing screen. By contrast, the metallic sheet 42 is the only required raw material in forming the finished rotary printing screen according to the present invention. Of course, it is possible to add adjacent layers, such as the coating 48 discussed above, to one or both surfaces 43a and 43b of the metallic sheet 42, but they are not necessary to practice the methods of the present invention.

Furthermore, the methods of the present invention substantially eliminate slag buildup during formation of the holes 46. More specifically, the relatively large percentage of nickel in the metallic sheet 42 (or any other metal that tends to vaporize rather than melt when struck by a laser beam) causes the ablated material to vaporize instead of melt and form slag. The vaporized material is then removed by the vacuum via the vacuum snout 40A and/or high-speed blower/vacuum outlet 40. Because slag is substantially eliminated according to the present invention, extra layers to support and remove slag are not required. Rather, the focused radiation is first directed to the metallic sheet or to the coating 48 that is permanently attached thereto.

The methods provided by the present invention also provide some unique opportunities for removing the waste products created when forming the holes 46. In a preferred embodiment, the nickel in the metallic sheet 42 vaporizes to form nickel and nickel oxide vapors. The vapors condense or coalesce into small particles, some of which are respirable and possibly carcinogenic. Thus, the laser engraving machine 20 includes the vacuum inlet 38 for introducing fresh air inside the cabinet 21, and a vacuum outlet as discussed above for removing and filtering the nickel and nickel oxide particles out of the air.

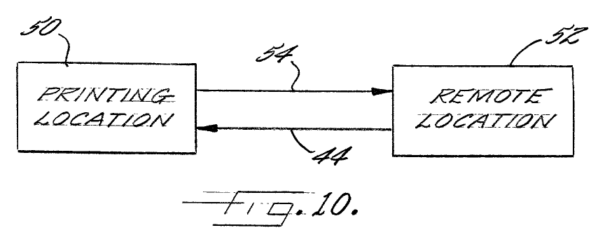

FIGS. 6-9 show various views of different shapes of the perforations or holes 46 that can be achieved using the laser 34 according to the present invention. In one embodiment shown in FIGS. 6-7, the hole 46 is cylindrical in shape, with the diameter of the cell on the inner surface 43b of the metallic sheet 42 effectively the same as the diameter of the hole on the outer surface 43a. In another embodiment shown in FIGS. 8-9, the hole 46 has a frustoconical shape, wherein the diameter of the hole 46 on the inner surface 43b of the metallic sheet is greater than the hole diameter on the outer surface 43a. The cross-sectional dimension of the hole 46 can be achieved through appropriate tuning of the laser 34. In particular, the focused radiation or laser beam emitted by the laser 34 has a generally conical shape. By appropriate tuning of the laser 34, the laser beam can be made more or less conical, which affects the shape of the holes 46 formed in the metallic sheet 42.

Advantageously, the frustoconical shape of the hole 46 shown in FIGS. 8-9 allows for a more precise application of the print paste to the printing substrate. Compared to the frustoconical holes formed by the Galvano process mentioned above, which disadvantageously force the print paste deep into the printing substrate, the frustoconical holes formed according to the present invention create a hydraulic pressure that is less than a cylindrical hole. As a result, the print paste can be more accurately applied to the substrate, which results in a more precise and better defined design on the printed substrate compared to conventional methods.

As stated above, it is not the intention of the present invention to limit its application to the use of a single type of laser. Lasers that operate in the infrared through ultraviolet frequencies may be suitable for use in practicing the teachings of the present invention. It is important that the choice of frequency employed by the laser 34 be such that the metal sheet 42 can be perforated by the focused energy of the laser. It is also important that the material forming the metallic sheet 42 substantially vaporizes when struck by the focused energy of the laser 34, so as to circumvent formation of residual slag around the edges of the holes 46.

It is envisioned that the present invention may be applicable to the manufacture of screens other than cylindrical screens. The teachings of this invention can be easily applied to production of flat screens and screens of non-uniform dimensions. Likewise, screens produced according to the teachings of the present invention may be used for applications other than rotary screen printing of substrates. These screens may be used for liquid filtration, for sieving of particulate materials, for cutting whiskers in conjunction with a blade, and the like.

FIG. 10 shows another method of manufacturing a printing screen that is operable for use in a rotary screen printing process. In particular, the method shown in FIG. 10 is particularly advantageous for screen printing operations that also have on-site screen manufacturing equipment, such as the laser engraving machine 20 discussed above. According to one embodiment, the method comprises providing the metallic sheet 42 at a screen printing operation 50 along with a laser 34 and other components of the laser engraving machine 20. Preferably, the screen printing operation 50 is provided with a plurality of metallic sheets 42 so that the screen printing operation can make multiple screens without waiting on replacement screens or sleeves to arrive. Also provided is a desired design 54, which can be in digital or non-digital form. Examples of non-digital forms are sketches, paintings, prints, and equivalents, while examples of digital forms are scanned images or equivalent forms that are in a pre-final configuration.

According to the present invention, the desired design 54 is sent from the printing location or operation 50 to a remote location 52. The remote location 52 can be on-site or off-site, and preferably is a third-party location. The remote location 52 is capable of converting the desired design 54 to a final digitized form, referred to above as the predetermined pattern or design 44, which is then sent back to the printing operation 50. The conversion is performed at the remote location 52 by a computer (not shown) having a processor, memory, and loaded software adapted for this process. Preferably, the predetermined pattern 44 is sent to the printing operation 50 electronically, such as via the Internet, although storage disks or equivalent mediums may also be sent using traditional methods. When the predetermined pattern 44 is received at the printing operation 50, the pattern is loaded as described above to produce the finished screen.

Advantageously, this method allows for the printing operation 50 to have an on-site laser engraving machine 20 to produce an unlimited number of finished screens quickly and easily. Accordingly, the printing operation 50 can make replacement screens on-site instead of having to reorder screens from an off-site manufacturer. And because replacement screens can be quickly manufactured, the printing operation 50 can make only the number of screens necessary to perform the desired operation, instead of ordering duplicate screens as has previously been the practice.

The following examples demonstrate some of the advantages of the present invention.

### EXAMPLE 1

A nickel sheet having a cylindrical shape and a thickness of 0.001 inches, a circumference of 27 inches, and a length of 138 inches is loaded into a laser screen engraving machine equipped with at least one Yag infrared laser. The cylinder is rotated at approximately 900 cm/sec. measured at the outer surface of the nickel cylinder. The Yag laser is controlled by the laser engraving machine, which causes the laser to direct a plurality of focused radiation pulses to a designated point on the outer surface of the cylinder. The nickel at the designated point vaporizes, and the process is repeated until a hole having a prescribed shape is defined through the cylinder, while the vaporized particles are removed by the vacuum. The hole in this example is cylindrical, so that the diameter of the hole is the substantially the same at the outer surface of the cylinder, the inner surface of the cylinder, and at points therebetween.

The laser is then caused to focus on another point on the surface of the cylinder according to the predetermined pattern programmed into the laser engraving machine, and the process is repeated until another perforation or hole is formed. The process is repeated again and again until all of the holes according to the predetermined pattern have been formed. Advantageously, several holes can be formed at the same time, as the laser directs pulses to several locations along a particular circumferential path on the metallic sheet as the sheet is rotated. The cylinder is then removed from the engraving machine, end caps are affixed for supporting the cylinder, and the screen is then ready for use as a rotary screen for the printing of textile fabrics, paper, vinyl wallpaper, and other materials.

### EXAMPLE 2

A nickel cylinder having a thickness of 0.003 inches is processed as described in Example 1 above, except that the laser is tuned so that the holes formed in the nickel cylinder are frustoconical in shape. The diameter of each hole at the outer surface of the cylinder is 0.005 inches, and the diameter of the hole at the inside of the cylinder is 0.003 inches.

### EXAMPLE 3

A printing location having a design desired to be formed on a rotary screen according to the present invention sends the design to a remote location, which converts the design into a final digital form that can be read and processed by a laser engraving machine located at the printing location. The final digital form is loaded into the laser engraving machine and the screen is formed as described in Examples 1 and 2.

The resulting rotary printing screen formed according to the present invention has several advantages over screens formed by conventional methods. First, the useful life of the rotary screen according to the present invention is greater than a convention lacquer screen, because the non-perforated or solid areas of the finished screen formed from the metallic sheet 42 resist damage and wear better than a mesh screen covered with hardened polymeric emulsion. Second, a rotary screen formed according to the present invention produces prints with sharper features, because there is no underlying mesh screen to interfere with flow of the print paste to the substrate. Third, the methods of the present invention allow the formation of frustoconical holes 46 in the metallic sheet, wherein the frustoconical holes have a greater diameter on the inner surface 43b of the metallic sheet 42 that contacts the substrate, which further improves the quality of the resulting print on the printing substrate. Finally, a screen formed by the methods of the present invention can be prepared in less than about two (2) hours, which is orders of magnitude faster than the 8-10 day cycle times for forming conventional screens.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A method of manufacturing a printing screen that is operable for use in a rotary screen printing process, the method comprising:
providing a metallic sheet formed from a single layer into a generally cylindrical shape to define a longitudinal axis;
providing a laser operable to emit focused radiation;
positioning the metallic sheet proximate the laser;
moving at least one of the metallic sheet and laser such that the metallic sheet and laser move relative to one another; and
forming a plurality of holes in the metallic sheet according to a predetermined pattern by directing focused radiation emitted from the laser into contact with only the metallic sheet.

2. A method according to claim 1, further comprising maintaining the metallic sheet in the generally cylindrical shape independent of an internal mandrel.

3. A method according to claim 1, wherein the moving step includes rotating the metallic sheet about the longitudinal axis thereof and moving the laser along a path parallel with the longitudinal axis of the metallic sheet.

4. A method according to claim 3, wherein the metallic sheet providing step includes providing a metallic sheet that is supported by supports spaced at opposite ends of the metallic sheet.

5. A method according to claim 1, wherein the positioning step includes positioning the metallic sheet proximate the laser in a laser engraving machine operable to rotate the metallic sheet about its longitudinal axis.

6. A method according to claim 1, wherein the forming step includes forming a plurality of holes in the metallic sheet by a pulsable laser having a power output of 25-100 watts.

7. A method according to claim 1, wherein the metallic sheet providing step includes providing a metallic sheet having a thickness of about 0.0005-0.010 inches.

8. A method according to claim 1, wherein the metallic sheet providing step includes providing a metallic sheet formed substantially from nickel.

9. A method according to claim 1, wherein the forming step includes forming a plurality of holes in the metallic sheet without the formation of slag.

10. A method according to claim 1, further comprising removing any waste particles created during the formation step using a vacuum.

11. A method according to claim 1, wherein the forming step includes forming at least one hole in the metallic sheet having a frustoconical shape, the hole having a relatively smaller diameter located radially inward of a relatively larger diameter.

12. A method according to claim 1, wherein the forming step includes forming at least one hole in the metallic sheet having a cylindrical shape.

13. A method according to claim 1, wherein the laser providing step includes providing a laser selected from one of the group consisting of an infrared laser and an ultraviolet laser.

14. A method of manufacturing a printing screen that is operable for use in a rotary screen printing process, the method comprising:
providing a metallic sheet formed from a single layer having two surfaces, at least one surface being exposed;
providing a laser operable to emit focused radiation;
positioning the metallic sheet proximate the laser;
moving at least one of the metallic sheet and laser such that the metallic sheet and laser move relative to one another; and
forming a plurality of holes in the metallic sheet by first directing focused radiation emitted from the laser to one of the two surfaces of the metallic sheet.

15. A method according to claim 14, wherein the forming step includes first directing focused radiation to the exposed surface of the metallic sheet.

16. A method according to claim 14, further comprising forming the metallic sheet into a generally cylindrical shape defining a longitudinal axis such that the metallic sheet independently maintains its cylindrical shape.

17. A method according to claim 16, wherein the moving step includes rotating the metallic sheet about a longitudinal axis thereof and moving the laser along a path parallel with the longitudinal axis of the metallic sheet.

18. A method according to claim 14, wherein the positioning step includes positioning the metallic sheet proximate the laser in a laser engraving machine.

19. A method according to claim 14, wherein the forming step includes forming a plurality of holes in the metallic sheet by a pulsable laser having a power output of 25-100 watts.

20. A method according to claim 14, wherein the providing step includes providing a metallic sheet having a thickness of about 0.0005-0.010 inches.

21. A method according to claim 14, wherein the providing step includes providing a metallic sheet formed substantially from nickel.

22. A method according to claim 14, wherein the forming step includes forming a plurality of holes in the metallic sheet by substantially vaporizing portions of the metallic sheet.

23. A method according to claim 14, further comprising removing any waste particles created during the formation step using a vacuum.

24. A method according to claim 14, wherein the forming step includes forming at least one hole in the metallic sheet having a frustoconical shape, the hole having a relatively smaller diameter located radially inward of a relatively larger diameter.

25. A method according to claim 14, wherein the forming step includes forming at least one hole in the metallic sheet having a cylindrical shape.

26. A method according to claim 14, wherein the laser providing step includes providing a laser selected from one of the group consisting of an infrared laser and an ultraviolet laser.

27. A method of manufacturing a printing screen that is operable for use in a rotary screen printing process, the method comprising:
providing a metallic sheet having a generally cylindrical shape defining a longitudinal axis;
providing a laser operable to emit radiation;
positioning the metallic sheet proximate the laser;
rotating the metallic sheet about the longitudinal axis thereof; and
forming a plurality of holes in the metallic sheet by directing radiation emitted from the laser and vaporizing portions of the metallic sheet such that slag is substantially eliminated during formation of the holes.

28. A method according to claim 27, wherein the positioning step includes supporting the metallic sheet by supports spaced at opposing ends of the metallic sheet.

29. A method according to claim 27, wherein the forming step includes moving the laser along a path parallel with the longitudinal axis of the metallic sheet while the metallic sheet is rotating.

30. A method according to claim 27, wherein the laser providing step includes providing a laser having a power output of 25-100 watts.

31. A method according to claim 27, wherein the metallic sheet providing step includes providing a metallic sheet having a thickness of about 0.0005-0.010 inches.

32. A method according to claim 27, wherein the metallic sheet providing step includes providing a metallic sheet formed substantially from nickel.

33. A method according to claim 27, further comprising removing any waste particles created during the formation step using a vacuum.

34. A method according to claim 27, wherein the forming step includes forming at least one hole in the metallic sheet having a frustoconical shape, the hole having a relatively smaller diameter located radially inward of a relatively larger diameter.

35. A method according to claim 27, wherein the forming step includes forming at least one hole in the metallic sheet having a cylindrical shape.

36. A method according to claim 27, wherein the laser providing step includes providing a laser selected from one of the group consisting of an infrared laser and an ultraviolet laser.

37. A method of manufacturing a printing screen, the method comprising:
positioning a metallic sheet proximate a laser, the laser operable to direct radiation toward the metallic sheet;
forming a plurality of holes in the metallic sheet such that carcinogenic particles are released to the atmosphere; and
filtering at least a least a portion of the carcinogenic particles from the atmosphere.

38. A method according to claim 37, wherein the forming step includes releasing carcinogenic particles containing at least nickel and nickel oxide vapors to the atmosphere.

39. A method of manufacturing a printing screen that is operable for use in a rotary screen printing process, the method comprising:
providing at a first location a metallic sheet formed into a generally cylindrical shape to define a longitudinal axis;
providing a laser operable to emit focused radiation;
providing a design desired to be formed on the printing screen;
sending the desired design to a remote location;
forming a final digital form of the desired design at the remote location;
sending the final digital form to the first location; and
forming a plurality of holes in the metallic sheet according to the final digital form of the desired design by directing focused radiation emitted from the laser into contact with the metallic sheet.

40. A method according to claim 39, wherein the metallic sheet providing step includes providing a metallic sheet formed substantially from nickel.

41. A method according to claim 39, wherein the laser providing step includes providing a laser that is part of a laser engraving machine.

42. A method according to claim 39, wherein the desired design providing step includes providing a desired design selected from the group consisting of non-digital works and digital works in pre-final form.

43. A method according to claim 39, wherein the sending to a remote location step includes sending the desired design to a third party location.

44. A method according to claim 39, wherein the forming step includes converting the desired design into final digital form.

45. A method of manufacturing a printing screen that is operable for use in a rotary screen printing process, the method comprising:
providing at a first location a metallic sheet formed into a generally cylindrical shape to define a longitudinal axis;
providing a laser operable to emit focused radiation;
providing a design desired to be formed on the printing screen;
sending the desired design to a remote location;
forming a final digital form of the desired design at the remote location;
sending the final digital form to the first location electronically; and
forming a plurality of holes in the metallic sheet according to the final digital form of the desired design by directing focused radiation emitted from the laser into contact with the metallic sheet.
